(19) United States
(12) Patent Application Publication
(10) Pub. No.: US 2013/0221805 A1
(43) Pub. Date: Aug. 29, 2013

(54) ULTRASONIC PROBE AND METHOD OF MANUFACTURING THE ULTRASONIC PROBE

(71) Applicant: Panasonic Corporation, (US)

(72) Inventors: Takashi OGURA, Osaka (JP); Yasuaki SUSUMU, Osaka (JP); Takayuki NAGATA, Osaka (JP); Koichi KUSUKAME, Nara (JP); Masako IKEDA, Osaka (JP)

(73) Assignee: PANASONIC CORPORATION, Osaka (JP)

(21) Appl. No.: 13/863,802

(22) Filed: Apr. 16, 2013

Related U.S. Application Data
(63) Continuation of application No. PCT/JP2012/002739, filed on Apr. 20, 2012.

(30) Foreign Application Priority Data
Apr. 21, 2011 (JP) 2011-095525
Jul. 13, 2011 (JP) 2011-154547

(51) Int. Cl. H01L 41/04; H01L 41/333

(52) U.S. Cl. CPC H01L 41/04; H01L 41/333
USPC 310/334; 419/7

(57) ABSTRACT

An ultrasonic probe includes: a piezoelectric transducer which generates ultrasonic waves when voltage is applied to the piezoelectric transducer; and an acoustic matching layer for matching acoustic impedances between the piezoelectric transducer and a subject. The acoustic matching layer includes a sintered layer having, across a surface of the sintered layer, a plurality of microscopic pores formed by sintering a composite including a bonding material and metal nanoparticles each having a size of one micron or less.

### CROSS REFERENCE TO RELATED APPLICATIONS

This is a continuation application of PCT International Application No. PCT/JP2012/002739 filed on Apr. 20, 2012, designating the United States of America, which is based on and claims priorities of Japanese Patent Applications No. 2011-095525 filed on Apr. 21, 2011, and No. 2011-154547 filed on Jul. 13, 2011. The entire disclosures of the above-identified applications, including the specifications, drawings and claims are incorporated herein by reference in their entirety.

### FIELD

One or more exemplary embodiments disclosed herein relate generally to an acoustic matching layer of an ultrasonic probe used for ultrasonic diagnosis, and to a method of manufacturing the ultrasonic probe.

### BACKGROUND

An ultrasonic diagnostic apparatus obtains information on the internal body of a subject by transmitting ultrasonic waves from an ultrasonic probe toward the subject, and receiving, by the ultrasonic probe, the ultrasonic waves reflected within the subject. More specifically, ultrasonic waves transmitted from piezoelectric transducers included in the ultrasonic probe of the ultrasonic diagnostic apparatus are emitted to the living body that is the subject. The emitted ultrasonic waves are reflected inside the body, travel backward, and are received by the piezoelectric transducers. Subsequently, the ultrasonic diagnostic apparatus visualizes the internal body of the subject, based on information on, for example, intensity of the ultrasonic waves received by the piezoelectric transducers, or response time taken from when the ultrasonic waves were emitted till the ultrasonic waves were received. An ultrasonic probe used for the ultrasonic diagnostic apparatus includes an array of piezoelectric transducers. In general, the ultrasonic probe includes, between a subject and the piezoelectric transducers, an acoustic matching layer for matching acoustic impedances.

In general, acoustic waves have a property of propagating through various mediums, and reflection occurs at the interface where different mediums contact, according to the difference of the acoustic impedances of the mediums. This hinders the acoustic wave transmission from one medium to another medium. The level of hindering increases as the difference in the acoustic impedances becomes greater. For example, in the case where a subject is a living body, the acoustic impedance of the body is 1.5 MRayls (=10̂6N·s/m3), and the acoustic impedance of a piezoelectric transducer comprising piezoelectric ceramic represented by lead zirconate titanate (PZT) is approximately 29 MRayls (ranging from 25 to 35 MRayls approximately depending on the materials of the piezoelectric transducer). Here, when Z1 represents the acoustic impedance of a medium 1, and Z2 represents the acoustic impedance of a medium 2, the reflectance of acoustic waves at the interface between the mediums is given by (Z2−Z1)/(Z1+Z2). Accordingly, if the piezoelectric transducers are directly contacted to the body for transmitting ultrasonic waves, approximately 90% of the ultrasonic waves are reflected at the interface between the piezoelectric transducers and the body without being transmitted to the body. On the other hand, even if ultrasonic waves are emitted toward the ultrasonic probe from another emitting element within the body, the ultrasonic waves are reflected at the interface between the body and the piezoelectric transducers. This hinders the reception of the emitted ultrasonic waves.

An acoustic matching layer is a member provided to prevent such reflections, and comprises materials having acoustic impedances between the body and the piezoelectric transducers. The acoustic matching layer changes the acoustic impedances in stages between the piezoelectric transducers and the body to reduce the reflectance in comparison to the case where the body and the piezoelectric transducers are directly contacted. As a result, the acoustic matching layer allows efficient transmission of ultrasonic waves into the body. For example, in the case where the acoustic waves emitted from the piezoelectric transducers having the above impedance are directly emitted to the body, the transmission rate of ultrasonic waves from the piezoelectric transducers to the body is approximately 19%. In the case where a layer with an acoustic impedance of 10 MRayls is provided between the piezoelectric transducers and the body, the transmission rate increases to 34%.

In recent years, a structure has been proposed which increases the ultrasonic frequency range and sensitivity by changing the acoustic impedances between the body and piezoelectric transducers in smaller ranges, using an acoustic matching layer having three or more layers (see Patent Literature (PTL) 1). The acoustic matching layer has a multilayer structure (hereinafter, referred to as a gradient matching layer) having gradient in acoustic impedance characteristics so that the acoustic impedance becomes closer to that of the body as the position of the layer becomes closer from the piezoelectric transducers toward the body. It is necessary to set each layer of the acoustic matching layer to have a desired acoustic impedance, so that ultrasonic waves are effectively transmitted into the body. Although it is possible to design such a gradient matching layer, it is not easy to obtain a material with an acoustic impedance which meets the design value, because the acoustic impedance is an intrinsic property of the material.

For example, most of plastic materials have an acoustic impedance ranging approximately from 2 MRayls to 4 MRayls. Hence, design under the range is relatively easy, but it is difficult to select a material with an acoustic impedance greater than 4 MRayls. Furthermore, in the case of metal materials, the metal materials, with some exceptions, have acoustic impedances which significantly exceed the value of the acoustic impedance of the piezoelectric transducer. More specifically, the absolute number of the materials having acoustic impedances ranging from 4 MRayls to 29 MRayls is small, which makes it difficult to adjust the acoustic impedance value to fall within a range from 4 MRayls and 29 MRayls. Accordingly, it is difficult to manufacture an acoustic matching layer which allows efficient transmission of ultrasonic waves between the piezoelectric transducers and the body.

In order to solve the problem, the techniques disclosed in PTL 2 to 4 achieve desired acoustic impedances by using composite materials.

### CITATION LIST

### Patent Literature

[PTL 1] Japanese Unexamined Patent Application Publication No. 60-100950
[PTL 2] Japanese Unexamined Patent Application Publication No. 2006-174991
[PTL 3] Japanese Unexamined Patent Application Publication No. 2009-528784
[PTL 4] Japanese Unexamined Patent Application Publication No. 2011-077572

### SUMMARY

### Technical Problem

However, the acoustic matching layers disclosed in PTL 2 to PTL4 do not allow ultrasonic waves generated by the piezoelectric transducers to be efficiently transmitted to the body.

One non-limiting and exemplary embodiment provides an ultrasonic probe having an acoustic matching layer which allows efficient transmission of ultrasonic waves to the body.

### Solution to Problem

In one general aspect, the techniques disclosed here feature an ultrasonic probe which includes: a piezoelectric transducer which generates ultrasonic waves when a voltage is applied to the piezoelectric transducer; and an acoustic matching layer for matching acoustic impedances between the piezoelectric transducer and a subject. In the ultrasonic probe, the acoustic matching layer includes a sintered layer having a plurality of microscopic pores across a surface of the sintered layer, the microscopic pores being formed by sintering a composite including a bonding material and metal nanoparticles each having a size of one micron or less, and the composite has a reducing agent added which acts on an oxide layer of a surface of each of the metal nanoparticles.

These general and specific aspects may be implemented using a method.

Additional benefits and advantages of the disclosed embodiments will be apparent from the Specification and Drawings. The benefits and/or advantages may be individually obtained by the various embodiments and features of the Specification and Drawings, which need not all be provided in order to obtain one or more of such benefits and/or advantages.

### Advantageous Effects

An ultrasonic probe according to one or more exemplary embodiments or features disclosed herein allows efficient transmission of ultrasonic waves between a piezoelectric transducer and a body. Furthermore, a method of manufacturing the ultrasonic probe according to one or more exemplary embodiments or features disclosed herein facilitates manufacturing of the ultrasonic probe which allows efficient transmission of ultrasonic waves between a piezoelectric transducer and a body.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is an external view of an ultrasonic diagnostic apparatus according to Embodiment 1.

FIG. 2 is a perspective view of an internal structure of an ultrasonic probe according to Embodiment 1.

FIG. 3 is an enlarged view of an acoustic matching layer according to Embodiment 1.

FIG. 4 shows a relationship between mixing ratio of metal particles and the acoustic impedance of an acoustic matching layer in the case where silver nanoparticles are used as metal particles, according to Embodiment 1.

FIG. 5 shows a relationship between mixing ratio of metal particles and the acoustic impedance of an acoustic matching layer in the case where copper nanoparticles are used as metal particles, according to Embodiment 1.

FIG. 6 shows a relationship between mixing ratio of resin particles and the acoustic impedance of an acoustic matching layer in the case where resin particles are used, according to Embodiment 1.

FIG. 7 is a flowchart of steps included in a method of manufacturing the acoustic matching layer of the ultrasonic probe according to Embodiment 1.

FIG. 8 is an enlarged view of an acoustic matching layer according to Embodiment 2.

FIG. 9 shows a structure of an acoustic matching layer according to Embodiment 3.

FIG. 10 shows acoustic characteristics of the acoustic matching layer according to Embodiment 3.

### DESCRIPTION OF EMBODIMENTS

### (Underlying Knowledge Forming Basis of the Present Disclosure)

In relation to the ultrasonic probe disclosed in the Background section, the inventors have found the following problem:

PTL 2 discloses an ultrasonic probe including an acoustic matching layer having polymer resin filled with powder comprising at least one material selected from metal, oxide, carbide, polymer, and hollow body. PTL 3 discloses an acoustic matching layer having a base material filled with nano-sized and micron-sized high-density metal particles. PTL 4 discloses an ultrasonic probe having an acoustic matching layer with acoustic impedances adjusted by mixing metal nanoparticles to resin, and sintering the resultant at a different sintering temperature.

As for the structure of the gradient matching layer including two or more layers, the precision of thickness of each layer and mechanical strength need to be paid attention to other than adjustment of the acoustic impedance of each layer to a desired value. Thus, the manufacturing method of the gradient matching layer also has to be performed considering such matters.

In general, the thickness of an acoustic matching layer that is considered to have an efficient transmission rate is ¼ wavelength of acoustic wave within the acoustic matching layer. The term “the thickness of an acoustic matching layer” here refers to a total thickness of all the layers included in an acoustic matching layer, in the case of the acoustic matching layer including a stack of two or more layers. Hence, in the case where the acoustic velocity within the acoustic matching layer is 1800 m/s and the central frequency is 9 MHz, an appropriate thickness of the acoustic matching layer is 50 μm approximately. However, if the number of layers of the gradient matching layer increases, an approximate thickness of each layer needs to be decreased to maintain the thickness of the acoustic matching layer. Accordingly, an approximate thickness of each layer of the acoustic matching layer is the value obtained by further dividing 50 μm by the number of the layers of the acoustic matching layer. In practice, the acoustic matching layer has a stack of layers each having a thickness of a few dozen μm. Specifically, the conventional method using an existing film material needs to polish the material to reduce the thickness of the material to a desired thickness. Stacking such layers causes problems in terms of time and cost.

Furthermore, in a general method of manufacturing an ultrasonic probe, after a piezoelectric transducer and an acoustic matching layer are bonded, the piezoelectric transducer and the acoustic matching layer that are integrated as a result of the bonding are cut into a width of 50 to 300 μm by a dicer from the acoustic matching layer side, thereby forming channels. Hence, it is important for the acoustic matching layer to be highly processable for dicing. In addition, the acoustic matching layer needs to have mechanical strength sufficient to prevent the stacked layers from cracking or peeling when dicing is performed.

However, the acoustic matching layers disclosed in PTL 2 to PTL 4 have difficulty in meeting all of the requirements of the acoustic impedance, and thickness precision or each layer, and the mechanical strength.

In PTL2, in the case where thermosetting epoxy resin is filled with two or more kinds of powder materials (each kind having a different density), different types of the powder materials naturally separate from one another, thereby forming layers having different acoustic impedances. Subsequently, the layers having different acoustic impedances thus formed are thermally hardened, thereby forming an acoustic matching layer. PTL 2 also discloses that the thickness of each layer is adjustable by increasing or decreasing the filing amount of the powder materials, and that the acoustic impedances are adjustable by changing the average particle size of the powder materials. However, this method may require the particle size exceeding 10 μm for adjusting impedances, hindering achievement of sufficient thickness precision for a layer of approximately a few dozen μm. Accordingly, it is difficult to form an acoustic matching layer which allows efficient transmission of ultrasonic waves, by using this method.

PTL3 discloses that an acoustic matching layer with an acoustic impedance ranging from 3 to 7 MRayls is achievable by mixing heavy particles and light particles to a base material. PTL 3 also discloses that an acoustic matching layer having an acoustic impedance ranging from 7 to 14 MRayls is achievable by mixing metal nanoparticles. However, a material having an acoustic impedance of 14 to 29 MRayls is required to ideally reduce reflection and increase the transmission efficiency of ultrasonic waves by forming a multilayer structure of the acoustic matching layer as a gradient matching layer. Specifically, simply mixing metal nanoparticles in such a manner does not achieve a high impedance layer with an acoustic impedance of 14 to 29 MRayls, hindering sufficient increase in transmission efficiency of ultrasonic waves.

PTL 4 discloses that an acoustic matching layer having an acoustic impedance of 6 to 15 MRayls achieved by mixing metal nanoparticles to adhesive resin and sintering the resultant. However, since the bonding strength between the layers is established by adhesiveness of the base material, it is difficult to maintain the bonding strength between the layers when the content of the metal nanoparticles is increased by a given amount or more. Specifically, if the content of the metal nanoparticles is increased to achieve the acoustic impedance of 15 to 29 MRayls through this method, the bonding strength between the layers of the acoustic matching layer (hereinafter, referred to as peeling strength) attenuates. Hence, even if a material having an acoustic impedance of 15 to 29 MRayls obtained by the technique of PTL 4 is used for a highest acoustic impedance layer of the acoustic matching layer to achieve efficient transmission of ultrasonic waves, it is difficult to provide sufficient peeling strength to the highest impedance layer. Accordingly, PTL 4 does not allow formation of an acoustic matching layer for efficient transmission of ultrasonic waves.

In one general aspect, the techniques disclosed here feature an ultrasonic probe which includes: a piezoelectric transducer which generates ultrasonic waves when a voltage is applied to the piezoelectric transducer; and an acoustic matching layer for matching acoustic impedances between the piezoelectric transducer and a subject. In the ultrasonic probe, the acoustic matching layer includes a sintered layer having a plurality of microscopic pores across a surface of the sintered layer, the microscopic pores being formed by sintering a composite including a bonding material and metal nanoparticles each having a size of one micron or less, and the composite has a reducing agent added which acts on an oxide layer of a surface of each of the metal nanoparticles.

With this, the acoustic matching layer for matching acoustic impedances between a piezoelectric transducer and a subject includes a sintered layer having a surface formed with a plurality of microscopic pores. The microscopic pores are formed by sintering a composite including a bonding material and metal nanoparticles each having a size of one micron or less. Hence, the microscopic pores formed in the surface of the sintered layer can be used for increasing the bonding strength between the sintered layer and an adjacent member. Even if a sintered layer is formed with a mixing ratio of metal particles increased to a given level or more, the peeling strength of the layer can be increased. As described above, a sintered layer, having a high acoustic impedance of 15 to 29 MRayls and a sufficient peeling strength between the sintered layer and an adjacent member, can be used for an acoustic matching layer, thereby increasing the transmission efficiency of ultrasonic waves between the piezoelectric transducer and the body.

Furthermore, it is possible to prevent the oxide layer of the metal particles from adversely affecting the process of sintering and from hindering the sintering, by coating the surface of the metal particles or the bonding material with antioxidant before sintering, or mixing reducing agent (hydrogen gas, carbon monoxide gas, carbon, etc) to solvent for diluting the metal particles and bonding material. As a result, it is possible to prompt bulk growth of the metal particles and of the bonding materials.

For example, it may be that the acoustic matching layer includes two of the sintered layers which are adjacent to each other, the two of the sintered layers being a first sintered layer and a second sintered layer, part of the first sintered layer penetrating into the microscopic pores of the second sintered layer.

With this, in the case of an acoustic matching layer including a stack of sintered layers, of the sintered layers adjacent to each other, part of one of the sintered layers penetrates into the microscopic pores of the other sintered layer. Accordingly, mechanical bonding force between the adjacent sintered layers can be increased due to anchor effects. Furthermore, compared with the case where part of one of the sintered layers does not penetrate into the microscopic pores of the other sintered layer, the area where the sintered layers contact can be increased, allowing an increase in the bonding force between the sintered layers. As a result, the peeling strength between the adjacent sintered layers can be increased.

Furthermore, it may be that the sintered layer is bonded to a member adjacent to the sintered layer via an adhesive layer, and part of the adhesive layer penetrates into the microscopic pores of the sintered layer.

With this, the sintered layer is bonded to an adjacent member via an adhesive layer, and part of the adhesive layer penetrates into the microscopic pores of the sintered layer. This allows an increase in the bonding force between the sintered layer and the adhesive layer for bonding the adjacent member, due to anchor effects. Furthermore, compared with the case where part of the adhesive layer does not penetrate into the microscopic pores of the sintered layer, the area where the sintered layer and the adhesive layer contact can be increased, allowing an increase in the bonding force between the sintered layer and the adhesive layer. Specifically, the bonding force between the sintered layer and an adjacent member bonded to the sintered layer via the adhesive layer can be increased.

For example, it may also be that the acoustic matching layer includes four or more layers, each of the four or more layers has a different acoustic impedance, a layer of the four or more layers positioned closer to the piezoelectric transducer has an acoustic impedance closer to an acoustic impedance of the piezoelectric transducer, and a layer of the four or more layers positioned closer to the subject has an acoustic impedance closer to an acoustic impedance of the subject, and at least one of the four or more layers is the sintered layer, and has an acoustic impedance of 15 MRayls or more. Furthermore, it may be that the sintered layer that is at least one of the four or more layers includes at least 90 percent by weight metal particles.

With the structure which includes at least 90 percent by weight metal material, it is possible to achieve an acoustic matching layer having an acoustic impedance of 15 to 29 MRayls which cannot be achieved by the conventional material. As a result, it is possible to achieve any acoustic impedance, for example, within a range from 2 to 29 MRayls. This allows an increase in freedom of design.

Accordingly, with such a structure, it is possible to achieve the optimal design of an acoustic matching layer which allows an increase in the transmission efficiency of ultrasonic waves between the body and an ultrasonic probe. This increases sensitivity and ultrasonic frequency range in comparison to a probe with a conventional gradient matching layer.

For example, it may be that the acoustic matching layer includes two of the sintered layers which are adjacent to each other, the two of the sintered layers being a first sintered layer and a second sintered layer, the first sintered layer including a first bonding material as the bonding material, the second sintered layer including a second bonding material as the bonding material, the first bonding material and the second bonding material comprising a same material, and

the first bonding material and the second bonding material are bonded to each other by being sintered.

With this, the acoustic matching layer includes two sintered layers which are adjacent to each other. The at least two adjacent sintered layers include bonding materials comprising the same material. Furthermore, the bonding material is a material which bonds when it is sintered. By using the same bonding material for the adjacent sintered layers in such a manner, compatibility between the adjacent layers is increased and jointing between the layers can be increased.

For example, it may be that the acoustic matching layer includes four or more layers, and at least one of the four or more layers is the sintered layer formed by mixing a bonding material and resin particles, the sintered layer having an acoustic impedance of 5 MRayls or less.

With this, the acoustic matching layer has a low impedance layer which is positioned closest to the body and which has an acoustic impedance of 5 MRayls or less that is closer to the acoustic impedance of the body. This increases the transmission efficiency of ultrasonic waves between the piezoelectric transducer and the body. The low impedance layer can be obtained by mixing, to a bonding material, resin particles instead of metal particles. The resin particles may be any kind of resin particles, such as acrylic, polyester series, polypropylene series, or amid-imide resin, as long as the impedance of the bonding material can be increased or decreased. Each kind of resin particles has its own intrinsic property; and thus, a choice may be made in view of the law, reliability, or the like in designing a target acoustic impedance.

Furthermore, it is desirable that the particle size of the resin particles is in the range from nano to a few microns inclusive. This is because the thickness of the matching layer required in design is at least a few dozen microns. The smaller the particle size is, less microscopic structural unevenness occurs. In addition, if the particle size is too large, when the particles are mixed with metal nanoparticles, sufficient mechanical strength can not be provided.

For example, it may be that the metal nanoparticles are either silver nanoparticles or copper nanoparticles. Furthermore, it may be that the bonding material includes one of a silica compound and heat-resistant organic polymer resin.

Furthermore, for example, it may be that the sintered layer is formed by sintering the composite while adding, to the composite, a reducing gas which acts on an oxide layer of a surface of each of the metal nanoparticles.

In this case, it is possible to prevent the oxide layer of the metal particles from adversely affecting the process of sintering and from hindering the sintering, by adding reducing agent (hydrogen gas, carbon monoxide gas, carbon, etc) to a sintering environment. As a result, it is possible to prompt bulk growth of the metal particles and of the bonding materials.

These general and specific aspects may be implemented using a method. A method of manufacturing an ultrasonic probe according to one aspect includes: applying a first composite including a bonding material and metal nanoparticles each having a size of one micron or less, after diluting the first composite with a solvent; drying the first composite applied in the applying of a first composite; manufacturing a sintered layer having a surface formed with microscopic pores, the microscopic pores being formed by sintering the first composite dried in the drying of the first composite; applying a second composite onto the sintered layer formed with the microscopic pores, after diluting the second composite with a solvent, the second composite including (i) a bonding material and (ii) metal nanoparticles or resin particles; applying a third composite onto the second composite applied in the applying of a second composite, after diluting the third composite with a solvent, the third composite including (i) a bonding material comprising a material same as a material of the bonding material included in the second composite, and (ii) metal nanoparticles or resin particles; and simultaneously sintering (i) a layer of the second composite applied in the applying of the second composite, and (ii) a layer of the third composite applied in the applying of the third composite.

Furthermore, the method may further includes applying a fourth composite different from the first composite onto the sintered layer formed with the microscopic pores, after diluting the fourth composite with a solvent; determining whether or not the fourth composite applied in the applying of a forth composite has penetrated into the microscopic pores of the sintered layer; drying the fourth composite applied in the applying of a fourth composite, after determined in the determining that the fourth composite has penetrated into the microscopic pores of the sintered layer; and sintering the fourth composite dried in the drying of the fourth composite. Furthermore, the method may further include applying an adhesive layer or a fifth composite different from the first composite onto the sintered layer formed with the microscopic pores; and removing air between the sintered layer and the adhesive layer to allow penetration of part of the adhesive layer or the fifth composite into the microscopic pores.

Hereinafter, embodiments are described in greater detail with reference to the accompanying Drawings. Each of the exemplary embodiments described below shows a general or specific example. The numerical values, shapes, materials, structural elements, the arrangement and connection of the structural elements, steps, the processing order of the steps etc. shown in the following exemplary embodiments are mere examples, and therefore do not limit the scope of the appended Claims and their equivalents. The present disclosure is defined by the appended Claims and their equivalents. Therefore, among the structural elements in the following exemplary embodiments, structural elements not recited in any one of the independent claims are not necessarily required to achieve the object of the present disclosure, but are described as arbitrary structural elements.

### Embodiment 1

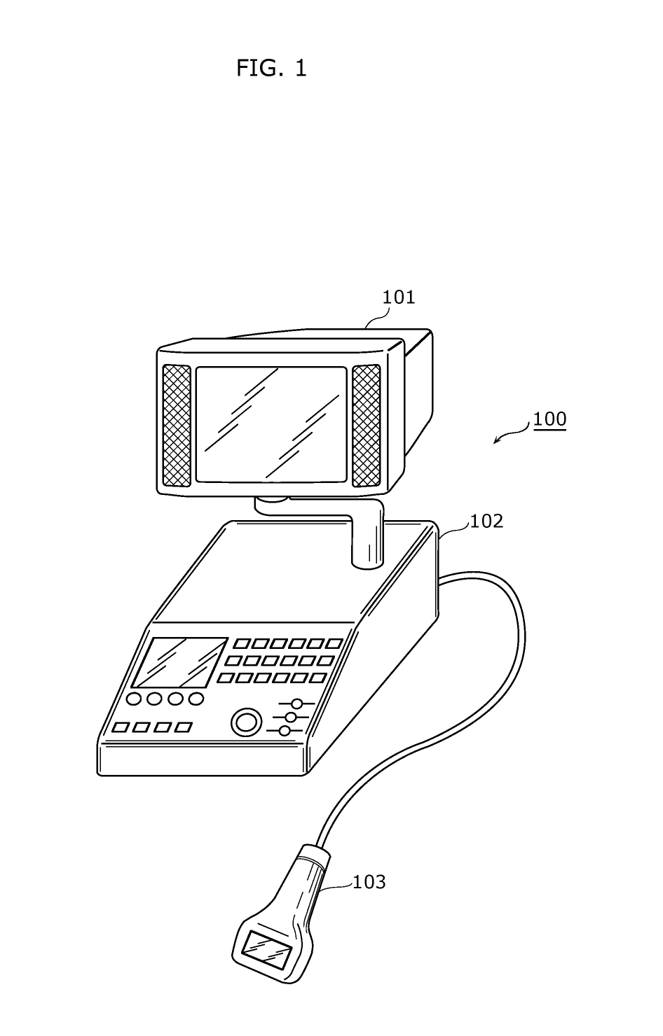

FIG. 1 is an external view of an ultrasonic diagnostic apparatus according to Embodiment 1. An ultrasonic diagnostic apparatus 100 is a digital ultrasonic diagnostic apparatus which generates, a tomographic image of a fetus, internal organs, a heart, or the like, by using, for example, an echo method. In addition, the ultrasonic diagnostic apparatus 100 automatically extracts, based on the obtained tomographic image, the outline of an object such as a fetus, internal organs, cancer tissue inside internal organs, or the interior wall of a heart, and simultaneously measures the volume of the extracted object or generates a three-dimensional (3D) image of the extracted object in real time. The ultrasonic diagnostic apparatus 100 includes, as main hardware, a display device 101, a main device 102, and an ultrasonic transmission and reception device 103.

The display device 101 is, for example, a cathode ray tube (CRT) with a clear touch panel or the like on the front screen. The display device 101 displays the obtained tomographic image, outline, measurement result, and the like in gray scale, in color, etc. and obtains an instruction on the images made by a touch pen or the like from an operator.

The ultrasonic transmission and reception device 103 includes: an ultrasonic probe 10 (to be described later) including, for example, ultrasonic transducers for transmitting and receiving ultrasonic waves and an acoustic lens; and a liquid crystal display unit which displays the value of the volume of an object and the like in real time.

The main device 102 includes, for example: a transmitting and receiving circuit for ultrasonic electronic scanning; a signal processing circuit including a digital signal processor (DSP), a central processing unit (CPU) or the like; and an image processing circuit. The main device 102 also includes, for example, a control panel, and a mouse including switches for allowing interactive communication with an operator, a track ball, a liquid crystal display unit or the like.

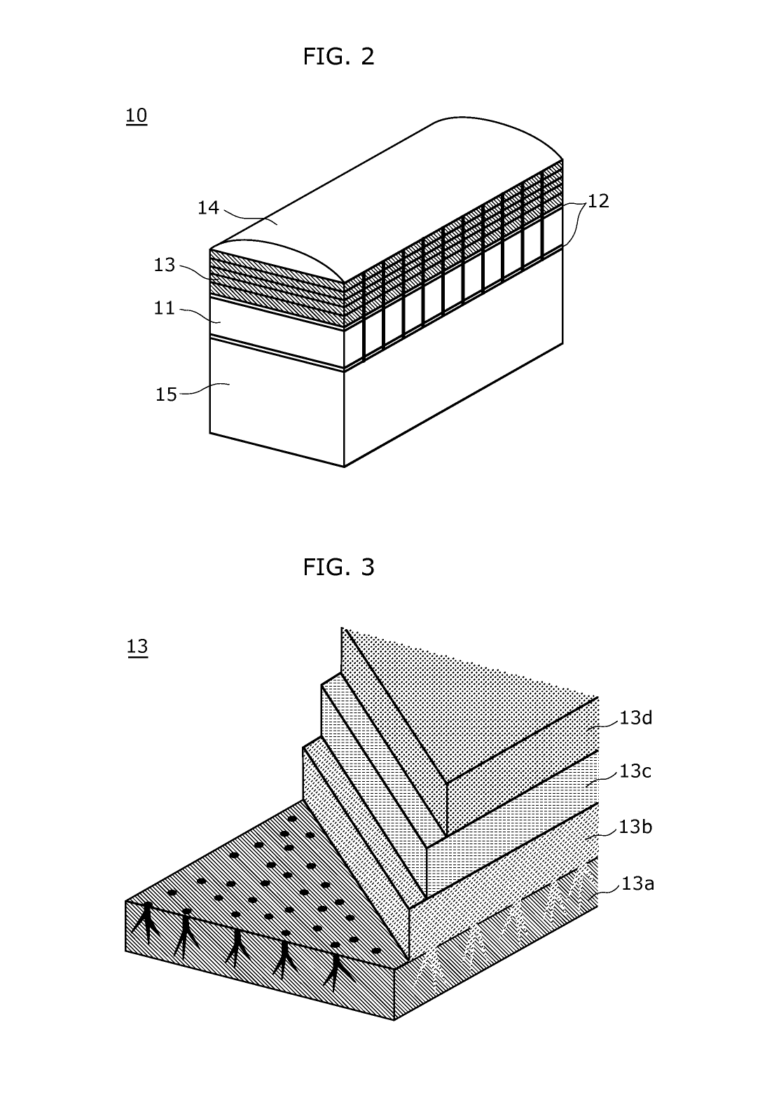

FIG. 2 is a perspective view of an internal structure of an ultrasonic probe according to Embodiment 1.

As shown in FIG. 2, the ultrasonic probe 10 includes a piezoelectric transducer 11, a driving electrode 12, an acoustic matching layer 13, an acoustic lens 14, and a backing 15. The piezoelectric transducer 11 comprises, for example, piezoelectric ceramics represented by lead zirconate titanate (PZT). The piezoelectric transducer 11 generates ultrasonic waves due to piezoelectric effects caused when voltage is applied to the piezoelectric transducer 11. The driving electrode 12 is an electrode for applying voltage to the piezoelectric transducer 11 to cause the piezoelectric effects. The acoustic matching layer 13 increases the transmission efficiency of ultrasonic waves between the piezoelectric transducer 11 and a subject by matching acoustic impedances between the piezoelectric transducer 11 and the subject. The acoustic lens 14 is a member for collecting the ultrasonic waves into a beam form. The backing 15 is a member which attenuates unnecessary ultrasonic waves generated by the piezoelectric transducer 11, that is, ultrasonic waves generated at a side opposite the subject.

Here, the acoustic matching layer 13 includes four layers each of which has a different acoustic impedance. The acoustic impedance of each layer has a value calculated based on exponential function adapted in an acoustic horn or the like. Here, for example, the acoustic impedances of the layers are designed to be 17 MRayls, 10 MRayls, 5 MRayls, and 3 MRayls in the order from the position closest to the piezoelectric transducer 11 toward the body. One of the layers has an impedance ranging from 15 to 29 MRayls which is not achievable by the conventional technique. In the case where the matching layer has four or more layers, the difference of the acoustic impedances between the layers can be decreased as described above. However, a material with an acoustic impedance of 15 MRayls or more, which is not achievable by the conventional technique, is required.

FIG. 3 is an enlarged view of the acoustic matching layer 13 according to Embodiment 1.

As shown in FIG. 3, the acoustic matching layer 13 includes a first layer 13a that has a high impedance, a second layer 13b, a third layer 13c, and a fourth layer 13d, in the order from the position closest to the piezoelectric transducer 11. Of the layers of the acoustic matching layer 13, at least the first layer 13a positioned closest to the piezoelectric transducer 11 comprises a composite material which has an acoustic impedance of 15 MRayls or more, and which includes at least 90 percent by weight metal particles. As shown in FIG. 3, the first layer 13a has a porous body. Specifically, the first layer 13a of the acoustic matching layer 13 is a sintered layer having a plurality of microscopic pores across the surface at a predetermined rate (for example, 20% or less) per unit area. The microscopic pores are formed by sintering a composite including a bonding material and metal nanoparticles each having a size of one micron or less. More specifically, the microscopic pores are uniformly distributed, without uneven portions, at the predetermined rate across the surface of the first layer 13a that is a sintered layer. For metal nanoparticles, silver nanoparticles or copper nanoparticles are used. Furthermore, for a bonding material, inorganic polymer material, such as silica compound is used. Furthermore, the bonding material is not limited to the inorganic polymer material, but may also be heat-resistant organic polymer resin. The second layer 13b of the acoustic matching layer 13 is a sintered layer formed by performing sintering in the similar manner to the first layer 13a. Part of the second layer 13b penetrates into the microscopic pores of the first layer 13a. Furthermore, the first layer 13a and the second layer 13b are adjacent two sintered layers in the acoustic matching layer 13. The first layer 13a includes a first bonding material and the second layer 13b includes a second bonding material. The first bonding material and the second bonding material comprising the same material. Furthermore, the first bonding material and the second bonding material are bonded to each other by being sintered. Of the layers of the acoustic matching layer 13, at least the fourth layer 13d positioned closest to the body that is a subject comprises a composite material including a bonding material and resin particles and having an acoustic impedance of 5 MRayls or less.

The mixing ratio of the metal particles or the resin particles is determined such that the first layer 13a, the second layer 13b, the third layer 13c, and the fourth layer 13d of the acoustic matching layer 13 have design acoustic impedances of 17 MRayls, 10 MRayls, 5 MRayls, and 3 MRayls, respectively.

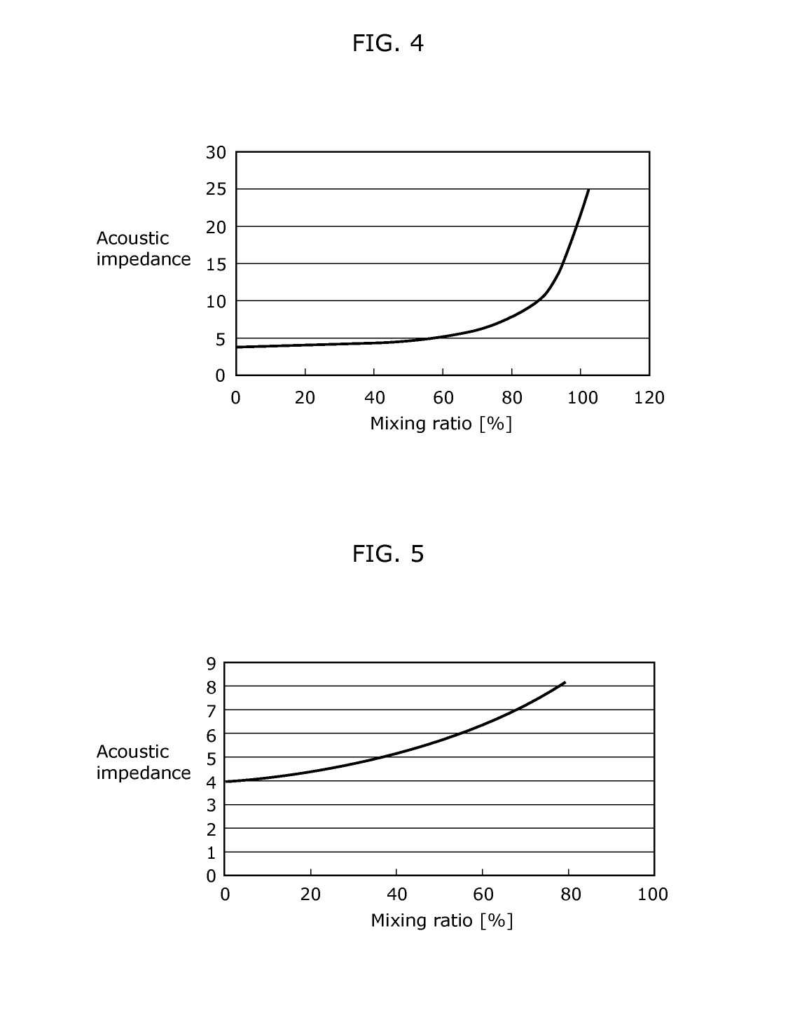

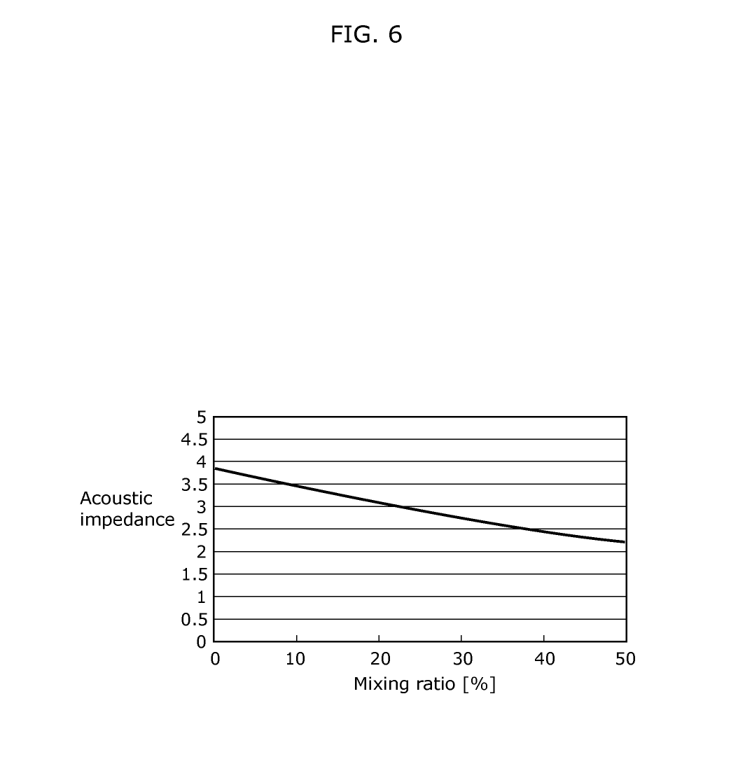

FIG. 4 shows a relationship between mixing ratio of metal particles and the acoustic impedance of an acoustic matching layer in the case where silver nanoparticles are used as metal particles, according to Embodiment 1. FIG. 5 shows a relationship between mixing ratio of metal particles and the acoustic impedance of an acoustic matching layer in the case where copper nanoparticles are used as metal particles, according to Embodiment 1. FIG. 6 shows a relationship between mixing ratio of resin particles and the acoustic impedance of an acoustic matching layer in the case where resin particles are used according to Embodiment 1. The mixing ratio shown in FIG. 4 to FIG. 6 is weight percentage of silver nanoparticles, copper nanoparticles, or resin particles relative to an entire amount of the composite with silica compound.

FIG. 4 shows that a composite material having an acoustic impedance within a range from 4 to 25 MRayls can be obtained by mixing silver nanoparticles and silica compound. Furthermore, FIG. 5 shows that a composite material having an acoustic impedance within a range from 4 to 8.5 MRayls can be obtained by mixing copper nanoparticles and silica compound. Furthermore, FIG. 6 shows that a composite material having an acoustic impedance within a range from 2.5 to 4 MRayls can be obtained by mixing resin particles and silica compound. More specifically, according to Embodiment 1, any impedance values can be designed between 1.5 MRayls that is the acoustic impedance of the body and 29 MRayls that is a general acoustic impedance of the piezoelectric transducer 11. Hence, as shown in FIG. 4 to FIG. 6, for example, the first layer 13a having an acoustic impedance of 17 MRayls comprises a composite material including silver nanoparticles and silica compound. The mixing ratio of the silver nanoparticles to the composite material is approximately 95%. Furthermore, for example, the second layer 13b having an acoustic impedance of 10 MRayls comprises a composite material including silver nanoparticles and silica compound. The mixing ratio of the silver nanoparticles to the composite material of the second layer 13b is 88% which is lower than that of the first layer 13a. Furthermore, for example, the third layer 13c having an acoustic impedance of 5 MRayls comprises a composite material including silver nanoparticles and silica compound. The mixing ratio of the silver nanoparticles to the composite material of the third layer 13c is approximately 58% which is lower than that of the second layer 13b. Furthermore, the third layer 13c may comprise a composite material including copper nanoparticles and silica compound. The mixing ratio of the copper nanoparticles to the composite material is approximately 38%. Furthermore, for example, the fourth layer 13d having an acoustic impedance of 3 MRayls comprises a composite material including resin particles and silica compound. The mixing ratio of the resin particles to the composite material is approximately 26%. The bonding material for the above cases is silica compound such as siloxane or silane coupling agent. If no problem is posed on the sintering temperature of metals, heat-resistant organic polymer resin may be used as a base material, and a porous body may be formed by adding a blowing agent or the like. In such a manner, a composite material having an acoustic impedance within a range from 2.5 to 25 MRayls can be obtained by selecting a kind of particles to be mixed to the silica compound serving as a bonding material and adjusting the mixing ratio of the particles.

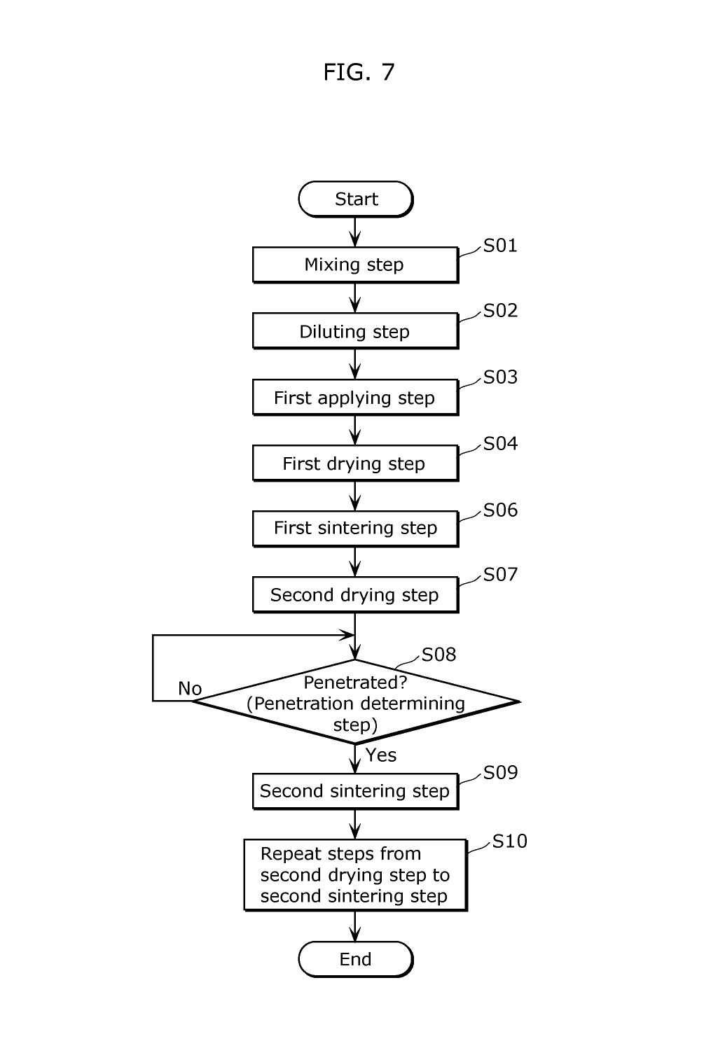

Next, a brief description is given of each step of a method of manufacturing the acoustic matching layer 13 of the ultrasonic probe 10 having the above structure. FIG. 7 is a flowchart of steps of the method of manufacturing the acoustic matching layer of the ultrasonic probe according to Embodiment 1. First, materials are mixed for each layer. A mixing step (S01) is performed in which silver nanopaste or copper nanoparticles (having a particle size of a few hundred nanometers) as metal particles, and, for example, silica compound as a bonding material, are mixed at a predetermined mixing ratio according to the acoustic impedance of each layer as described above.

The first layer 13a that is a high impedance layer is formed so as to include at least 90 percent by weight metal material, but may include 100 percent by weight metal material without mixing a bonding material. Furthermore, for the fourth layer 13d having a lowest impedance, instead of metal particles, resin particles that are plastic powder, such as acrylic, are mixed to the bonding material same as those included in the other layers.

The resultant mixture is diluted with aqueous medium in a diluting step (S02). In the diluting step, defoaming is further performed on the diluted mixture by stirring and decompression. The resultant mixture becomes application liquid to be applied to form the first layer 13a to fourth layer 13d depending on the mixing ratio.

Next, in a first applying step (S03), an applying device applies application liquid that is a composite including materials for the first layer 13a onto a substrate, such as aluminum or copper, to obtain a predetermined thickness. Here, as an applying device used for manufacturing the acoustic matching layer 13, for example, a spray coater may be used. The spray coater is capable of accurately manufacturing a layer of a few dozen μm approximately. The composite applied in the first applying step is dried in a first drying step (S04). The dried composite is then sintered at low temperature that is a few hundred degrees in a first sintering step (S05). When the first drying step is completed, solvent slightly remains within the layer. By performing the first sintering step of Step S05 on the first layer 13a in this state, the slightly remaining solvent evaporates, and the portions where the solvent has evaporated become microscopic pores. As a result, the first layer 13a becomes a porous body having a surface formed with microscopic pores. Each of the microscopic pores has a size of 100 μm or less. The desired particle size of the material for the second layer 13b is a few dozen μm approximately so that the second layer 13b penetrates into the microscopic pores. The size of the microscopic pores formed here may be changed by increasing or decreasing the ratio of the composite diluted in the diluting step of Step S02 to solvent. More specifically, the size of the microscopic pores formed in the surface of the sintered first layer 13a can be increased by increasing the amount of solvent relative to the composite. On the other hand, the size of the microscopic pores formed in the surface of the first layer 13a can be decreased by decreasing the amount of solvent relative to the composite.

Next, in a second applying step (S06), a second layer 13b is applied onto the first layer 13a so that the second layer 13b has a predetermined thickness. The resultant is dried in a second drying step (S07). The drying is performed after a sufficient time period from S06 to allow the application liquid of the second layer 13b to penetrate into the microscopic pores of the surface of the first layer 13a. In a penetration determining step (S08), whether or not a predetermined time period has passed is checked to determine whether or not the application liquid of the second layer 13b applied on the first layer 13a has penetrated into the microscopic pores of the surface of the first layer 13a. Specifically, when a predetermined time period has passed (Yes in S08), processing proceeds to a next second sintering step (S09), and when a predetermined time period has not passed (No in S08), processing returns to Step S08.

Next, after the second layer 13b is dried, the second sintering step (S09) is performed in which the second layer 13b is sintered in a state where part of the second layer 13b has penetrated into the microscopic pores of the surface of the first layer 13a. By manufacturing the layers in such a manner that part of the second layer 13b penetrates into the microscopic pores of the surface of the first layer 13a, sufficient peeling stress can be obtained between the first layer 13a and the second layer 13b due to anchor effects even when the ratio of the bonding material included in the first layer 13a is low. Along with anchor effects (mechanical bonding), bonding is achieved in a state where part of the second layer 13b penetrates into the microscopic pores of the surface of the first layer 13a (chemical bonding). The area of the interface between the first layer 13a and the second layer 13b in this state is larger than the area of the interface between the two layers in a case where flat planes without microscopic pores are bonded. Specifically, the area of the interface between the first layer 13a and the second layer 13b is larger than the case where two flat planes are bonded; and thus, sufficient peeling strength can be obtained between the first layer 13a and the second layer 13b. Furthermore, after the sintering of the second layer 13b, the second layer 13b has a porous body; and thus, applying and sintering of the third layer 13c and the fourth layer 13d are sequentially performed in the similar manner in that the second layer 13b is applied onto the first layer 13a. As a result, a matching layer having high peeling strength between the layers can be manufactured. Specifically, after the second sintering step, steps from the second drying step (S07) to the second sintering step (S09) are repeatedly performed, thereby forming the third layer 13c and the fourth layer 13d (S10). The method of manufacturing the acoustic matching layer of the ultrasonic probe is completed when the fourth layer 13d is formed.

The acoustic matching layer 13 thus manufactured is peeled from the substrate, bonded to the driving electrode 12 burnt onto the surface of the piezoelectric transducer 11, and cut into a width of 50 to 300 μm by using a dicer from the acoustic matching layer 13 side, thereby forming channels. Here, insufficient bonding force between the layers of the acoustic matching layer results in peeling at the time of dicing. However, in the acoustic matching layer 13 according to Embodiment 1, the first layer 13a that is a high impedance layer having a small mixing ratio of the bonding material and the second layer 13b are mechanically bonded using the anchor effects; and thus, peeling strength between the layers can be increased. Specifically, the acoustic matching layer 13 has such a peeling strength that prevents layers from easily peeling even at the time of dicing. Subsequently, the acoustic lens 14 and the backing 15 are attached, thereby completing the main part of the ultrasonic probe 10.

According to the ultrasonic probe 10 in Embodiment 1, respective layers 13a to 13d of the acoustic matching layer 13, which matches acoustic impedances between the piezoelectric transducer and the body as a subject, are sintered layers each having a surface formed with microscopic pores. The microscopic pores are formed by sintering a composite including a bonding material and metal nanoparticles each having a size of one micron or less. Specifically, the acoustic matching layer 13 includes the sintered layers as described above. In the case of the acoustic matching layer 13 having a stack of the first layer 13a to the fourth layer 13d that are sintered layers as above, part of one of the adjacent sintered layers penetrates into the microscopic pores of the other sintered layers. More specifically, for example, part of the second layer 13b penetrates into the microscopic pores of the first layer 13a. Accordingly, mechanical bonding force between the two adjacent sintered layers can be increased due to anchor effects. Furthermore, compared with the case where part of one of the sintered layers do not penetrate into the microscopic pores of the other sintered layer, the area where the two sintered layers contact can be increased, allowing an increase in the bonding force between the sintered layers. As a result, the peeling strength between the adjacent sintered layers can be increased.

Furthermore, according to the ultrasonic probe 10 in Embodiment 1, the first layer 13a of the acoustic matching layer 13 is a sintered layer having a plurality of microscopic pores across the surface at a predetermined rate (20% or less) per unit area. The microscopic pores are formed by sintering a composite including a bonding material and metal nanoparticles each having a size of one micron or less. Since the microscopic pores are uniformly formed across the surface of the first layer 13a at a predetermined rate per unit area without uneven portions, anchor effects can be uniformly obtained across the entire interface between the first layer 13a and the second layer 13b without uneven portions by allowing penetration of part of the adjacent second layer 13b into the microscopic pores of the first layer 13a. As a result, the peeling strength can be increased.

Furthermore, according to the ultrasonic probe 10 in Embodiment 1, the first layer 13a of the acoustic matching layer 13 includes at least 90 percent by weight metal particles. This allows the first layer 13a having an acoustic impedance of 15 to 29 MRayls. The first layer 13a includes a larger amount of metal particles than the bonding material and is not easily bonded to the second layer 13b. However, since the first layer 13a has a surface with the microscopic pores formed by sintering, peeling strength between the first layer 13a and the second layer 13b can be increased by allowing part of the second layer 13b to penetrate into the microscopic pores of the first layer 13a.

Accordingly, even if a sintered layer is formed having a mixing ratio of metal particles increased to a predetermined ratio or more, the peeling strength can be increased by forming the microscopic pores in the surface of the sintered layer and allowing part of an adjacent member to penetrate into the microscopic pores. As described above, a sintered layer having a high acoustic impedance of 15 to 29 MRayls and a sufficient peeling strength with an adjacent member can be used for an acoustic matching layer, thereby increasing transmission efficiency of ultrasonic waves between the piezoelectric transducer and the body.

Furthermore, according to the ultrasonic probe 10 in Embodiment 1, the sintered layers 13a to 13d of the acoustic matching layer 13 include bonding materials comprising the same material. Specifically, the acoustic matching layer 13 includes two sintered layers that are adjacent to each other. The two adjacent sintered layers include bonding materials comprising the same material. Furthermore, the bonding material is a material which bonds when it is sintered. By using the same bonding material for adjacent sintered layers in such a manner, compatibility between the adjacent layers is increased and jointing between the layers can be increased.

Furthermore, according to the ultrasonic probe 10 in Embodiment 1, the fourth layer 13d is positioned closest to the body, out of the sintered layers 13a to 13d of the acoustic matching layer 13. The fourth layer 13d is a low impedance layer having an impedance of 5 MRayls or less that is closer to the impedance of the body. The fourth layer 13d that is a low impedance layer as described above can be achieved by mixing, to the bonding material, resin particles instead of metal particles.

Furthermore, according to the ultrasonic probe 10 in Embodiment 1, the surface of the metal particles or the bonding material is coated with antioxidant before sintering is performed, reducing agent (hydrogen gas, carbon monoxide gas, carbon or the like) is added to a sintering environment, or reducing agent is mixed to solvent for diluting the metal particles and the bonding material. This prevents the oxide layer of the metal particles from adversely affecting the process of sintering and from hindering the sintering. As a result, it is possible to prompt bulk growth of metal particles and of the bonding materials.

Furthermore, according to the ultrasonic probe 10 in Embodiment 1, the metal particles used for the acoustic matching layer 13 are metal nanoparticles each having a size of one micron or less, in particular, metal nanoparticles each having a size of less than a few hundred nanometers. These metal nanoparticles have a high reactivity due to the size of the surface area, and start to be sintered at 100 degrees to 350 degrees. Although the sintering starting temperature varies depending on the particle size, it is significantly lower than the melting point of metals. In such a manner, the metal nanoparticles are sintered at a relatively lower temperature environment than the melting point of metals, and grow to bulk state of metal; and thus, the sintered layer achieves higher acoustic impedance than the case where a sintered layer is formed by a composite in which metal particles are singly dispersed.

Here, the strength of the sintered powders increases due to the bulk growth of the metal particles. Furthermore, the bonding material penetrates into the voids of the metal bulk formed of the metal particles, and bulk growth of bonding material is also carried out while penetrating into the voids of the metal bulk. As described, the metal powder and the bonding material of the sintered layer are sintered, and bulk growth is carried out in a state where the metal powder and the bonding material are intertwined with each other. The composite material of the sintered layer enhances the mechanical strength, leading to an increase in breaking strength of the sintered layer.

In the ultrasonic probe 10 according to Embodiment 1, after the application liquid of the second layer 13b is applied onto the first layer 13a that has already been sintered, whether or not the application liquid of the second layer 13b has penetrated into the microscopic pores of the surface of the first layer 13a is determined by checking if a predetermined length of time has passed. The determination may be made by checking if the amount of bubbles generated when the application liquid of the second layer 13b is applied onto the first layer 13a has decreased. Examples of the method for determining a decrease in the amount of bubbles include performing image analysis on images captured by a camera.

Furthermore, in the ultrasonic probe 10 according to Embodiment 1, penetration of the application liquid of the second layer 13b into the microscopic pores of the surface of the first layer 13a is achieved by leaving sufficient time at ordinary temperature. However, instead of taking sufficient time, an air removing step may be performed in which air between the application liquid of the second layer 13b applied and the sintered first layer 13a is actively removed, to allow the application liquid of the second layer 13b to penetrate into the microscopic pores of the surface of the first layer 13a. More specifically, instead of the penetration determining step, the air removing step may be performed. An example of the air removing step is actively allowing the application liquid of the second layer 13b to penetrate into the microscopic pores of the surface of the first layer 13a by reducing the pressure after the application liquid of the second layer 13b is applied. Another example is while the first layer 13a is hot by preheating the first layer 13a or while the first layer 13a after the sintering is still hot and before it is cooled down, the second layer 13b is applied in a state where the air inside the microscopic pores of the first layer 13a is expanded, to prompt the penetration of the application liquid of the second layer 13b into the microscopic pores of the first layer 13a when the temperature of the first layer 13a is back to ordinary temperature.

Furthermore, in the ultrasonic probe 10 according to Embodiment 1, penetration of the application liquid of the second layer 13b into the microscopic pores of the surface of the first layer 13a is achieved by leaving sufficient time at ordinary temperature and performing the air removing step; however, other methods may be used. It may be that after sintering the first layer 13a, a predetermined level of pressure is applied to the application liquid of the second layer 13b using a squeegee (spatula) to allow penetration of the application liquid of the second layer 13b into the microscopic pores of the first layer 13a.

Furthermore, in the ultrasonic probe 10 according to Embodiment 1, the acoustic matching layer 13 is formed by sintering the first layer 13a first, then applying and sintering the second layer 13b, and sequentially sintering the third layer 13c and the fourth layer 13d in the similar manner; however, the method is not limited to sintering the layers one by one. For example, relative to the layers, out of the second layer 13b to the fourth layer 13d, having a smaller mixing ratio of metal particles or resin particles and a larger mixing ratio of the bonding material, the acoustic matching layer 13 may be formed by successively applying layers, and simultaneously sintering the layers, instead of applying one layer and then sintering the layer.

More specifically, in the fourth applying step, a composite including a bonding material and metal nanoparticles or resin particles is applied onto the first layer 13a that is a sintered layer formed with microscopic pores, after diluting the composite with solvent. After the fourth applying step, a fifth applying step is performed in which a composite including the metal nanoparticles or resin particles and the same bonding material as that of the composite applied in the fourth applying step is diluted with solvent and is applied onto the composite applied in the fourth applying step. Subsequently, a third sintering step may be performed in which the two layers of the composite applied in the fourth applying step and the composite applied in the fifth applying step are simultaneously sintered. In such a case, the bonding materials of the respective layers are sintered, thereby increasing the peeling strength between the layers.

Furthermore, in the ultrasonic probe 10 according to Embodiment 1, each layer of the acoustic matching layer 13 has an acoustic impedance set to a desired value by changing the mixing ratio of the metal particles and the bonding material; however, the acoustic impedance value may be set by any other methods. For example, the acoustic impedance value may be controlled by changing the sintering temperature conditions or sintering length conditions of a composite including metal particles and a bonding material at a predetermined mixing ratio. More specifically, by reducing the sintering length and the sintering temperature, less necking occurs between the metal nanoparticles, which allows a decrease in the acoustic impedance. On the other hand, by increasing the sintering length and the sintering temperature, the bonding strength between the metal nanoparticles increases, which allows an increase in the acoustic impedance.

### Embodiment 2

Embodiment 2 is different from Embodiment 1 only in the structure of the acoustic matching layer; and thus, descriptions of the other constituent elements are omitted.

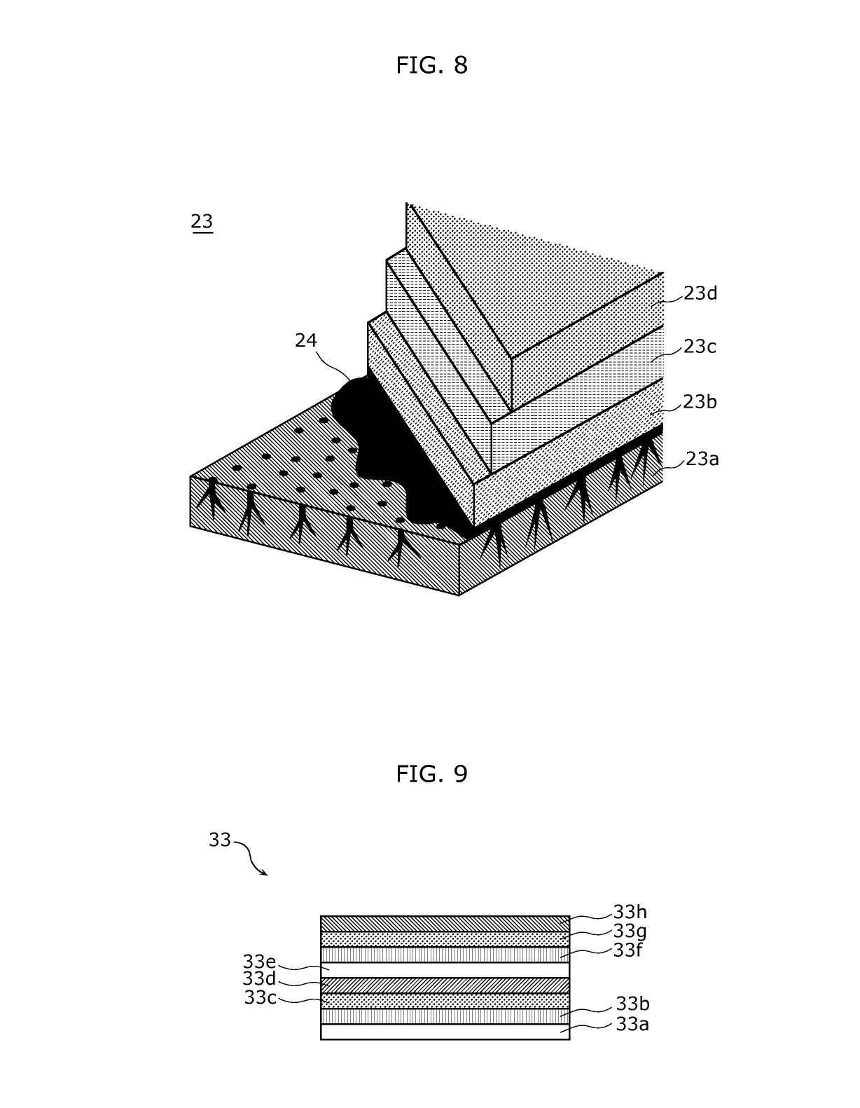

FIG. 8 is an enlarged view of an acoustic matching layer according to Embodiment 2. As shown in FIG. 8, an acoustic matching layer 23 includes a first layer 23a that has a high impedance, a second layer 23b, a third layer 23c, a fourth layer 23d, and an adhesive layer 24.

Of the layers of the acoustic matching layer 23, at least the first layer 23 positioned closest to a piezoelectric transducer 11 comprises a composite material which has an acoustic impedance of 15 MRayls or more and which includes at least 90 percent by weight metal particles. As shown in FIG. 8, the first layer 23a has a porous body. Each of the second layer 23b to the fourth layer 23d comprises a film material. The adhesive layer 24 penetrates into the microscopic pores of the first layer 23a. Specifically, the first layer 23a and the second layer 23b are bonded by adhesive agent that is the adhesive layer 24, and part of the adhesive layer 24 penetrates into the microscopic pores formed in the surface of the first layer 23a.

The acoustic matching layer 23 having such a structure is formed by applying, onto a substrate, the first layer 23a that has a porous body first, and then drying and sintering the first layer 23a, in the similar manner to Embodiment 1. After the formation of the first layer 23a, the adhesive layer 24 is applied onto the first layer 23a, penetration of the adhesive layer 24 into the microscopic pores of the surface of the first layer 23a is caused, and the second layer 23b to the fourth layer 23d that are film materials are sequentially bonded. The methods similar to those in Embodiment 1 may be used for allowing the adhesive layer 24 to penetrate into the microscopic pores of the first layer 23a. More specifically, the adhesive layer 24 may be allowed to penetrate into the microscopic pores of the surface of the first layer 23a through the penetration determining step, the air removing step, or by using a squeegee. By doing so, the sufficient peeling strength between the first layer 23a and the second layer 23b can be obtained, because even if the first layer 23a includes a small amount of bonding material and at least 90 percent by weight metal particles, sufficient strength between the first layer 23a and the adhesive layer 24 is obtained due to anchor effects. Furthermore, the second layer 23b, the third layer 23c, and the fourth layer 23d that are film materials may be firmly bonded to each other by using adhesive agent dedicated to film materials. Alternatively, porous film materials may be used so that adhesive agent is also mechanically bonded to the film materials due to anchor effects.

In the similar manner to the matching layer 13 according to Embodiment 1, the acoustic matching layer 23 thus manufactured is peeled from the substrate, and is attached to the driving electrode 12 burnt onto the surface of the piezoelectric transducer 11, and is cut into a width of 50 to 300 μm from the acoustic matching layer 23 side by using a dicer, thereby forming channels. Here, also in Embodiment 2, in the similar manner to Embodiment 1, the acoustic matching layer 23 has sufficient bonding force between the layers; and thus, the first layer 23a and the second layer 23b have peeling strength therebetween that does not allow peeling even at the time of dicing. Subsequently, the acoustic lens 14 and the backing 15 are attached, thereby completing the main part of the ultrasonic probe.

According to the ultrasonic probe 10 in Embodiment 2, in the acoustic matching layer 23, the first layer 23a that is a sintered layer is bonded to the second layer 23b that is an adjacent member via the adhesive layer 24, and part of the adhesive layer 24 penetrates into the microscopic pores of the sintered layer. Accordingly, the bonding force between the first layer 23a and the adhesive layer for bonding the adjacent second layer 23b can be increased due to anchor effects. Furthermore, compared with the case where part of the adhesive layer does not penetrate into the microscopic pores of the first layer 23a that is a sintered layer, the area where the first layer 23a and the adhesive layer contact can be increased, allowing an increase in the bonding force between the first layer 23a and the adhesive layer 24. Specifically, it is possible to increase the bonding force between the first layer 23a that is a sintered layer and the second layer 23b adjacent to the first layer 23a and bonded to the first layer 23a via the adhesive layer 24.

Furthermore, according to the ultrasonic probe 10 in Embodiment 2, in the acoustic matching layer 23, only the high impedance layer that cannot be obtained by a conventional film material comprises a composite material obtained by mixing and sintering a metal material. The other film material layers having acoustic impedances lower than that of the high impedance layer comprises an existing film material. The method using the existing film materials has problems in time and cost when the materials are polished into a predetermined thickness. However, if a design is possible in which a film material can be used without polishing, combination of the above composite material and the film material simplifies the method. Furthermore, such a structure also provides an ultrasonic probe which has an increased resolution, ultrasonic frequency range and reliability, because the peeling strength between the layers of the acoustic matching layer 23 is high in the similar manner to Embodiment 1.

In the acoustic matching layer 23 of the ultrasonic probe according to Embodiment 2, the first layer 23a that is a sintered layer is bonded to the second layer 23b that is a film material via the adhesive layer 24; however, as in Embodiment 1, both the first layer and the second layer may be sintered layers. Specifically, as to the bonding of the sintered layer that is similar to the first layer 13a, too, it may be that an adhesive layer is provided, adhesive agent is caused to sufficiently penetrate into the first layer in advance, and after the air within the layer is removed, the second layer is applied.

The following describes the specific steps. First, the first layer is formed by sintering so as to have a porous body. Next, for example, adhesive agent made of adhesive heat-resistant resin is applied onto the first layer to allow the adhesive agent to penetrate into the microscopic pores of the surface of the first layer. Here, the first layer is immersed into a solution of adhesive agent to completely remove the air within the first layer. Alternatively, it may be that the pressure is reduced after the adhesive agent is applied and the air between the first layer and the adhesive agent is removed, to completely remove the air between the first layer and the adhesive agent. After the adhesive agent fills the microscopic pores of the first layer, drying is performed after spare adhesive agent on the surface of the first layer is lightly cleaned off so that the adhesive layer between the first layer and the second layer does not become too thick. Alternatively, instead of performing the drying, preliminary sintering may be performed at approximately 100 degrees. Subsequently, the second layer is applied onto the adhesive layer, and dried and sintered.

The method above also increases the peeling strength by firmly bonding the composite materials.

Furthermore, the piezoelectric transducer 11 of the ultrasonic probe according to Embodiment 1 and Embodiment 2 comprises piezoelectric ceramic; however, instead, it may have a structure such as a piezoelectric micro-machined ultrasonic transducer (pMUT). In this case, the acoustic matching layers 13 and 23 may be directly formed on the pMUT by using a spray coater.

### Embodiment 3

In Embodiments 1 and 2, the acoustic matching layer having four layers has been described as an example; however, the number of the layers may vary. For example, as shown in FIG. 9, an acoustic matching layer 33 may have eight layers (a first layer 33a to an eighth layer 33h). FIG. 9 shows a structure of an acoustic matching layer according to Embodiment 3. Each of the layers 33a to 33h of the eight-layered acoustic matching layer 33 has a different acoustic impedance. In the order from the first layer 33a to the eighth layer 33h, the acoustic impedances vary from 25 to 2.5 MRayls depending on the design. In this case, the first layer 33a is positioned closest to the piezoelectric transducer 11, and the eighth layer 33h is positioned closest to the acoustic lens 14. Table 1 below shows the acoustic impedances of the layers 33a to 33h of the acoustic matching layer 33. In the similar manner to the acoustic matching layer 13 described in Embodiment 1, these acoustic impedance values are calculated based on the exponential function adapted in an acoustic horn or the like, and are designed to increase transmission efficiency. It is to be noted that the values shown in Table 1 are mere examples in Embodiment 2 as the values to be set vary according to the impedance of the piezoelectric element or as the values are optimized by changing the constant number of the horn function.

TABLE 1

| | | Acoustic impedance |
|---|---|---|
| Layer number | Constituent material | [MRayls] |
| 8^{th} layer | Third polymer nanoparticle layer | 2.1 |
| 7^{th} layer | Second polymer nanoparticle layer | 3.0 |
| 6^{th} layer | First polymer nanoparticle layer | 4.2 |
| 5^{th} layer | Third copper nano layer | 5.9 |
| 4^{th} layer | Second copper nano layer | 8.3 |
| 3^{rd} layer | First copper nano layer | 11.6 |
| 2^{nd} layer | Second silver nano layer | 16.3 |
| 1^{st} layer | First silver nano layer | 22.8 |

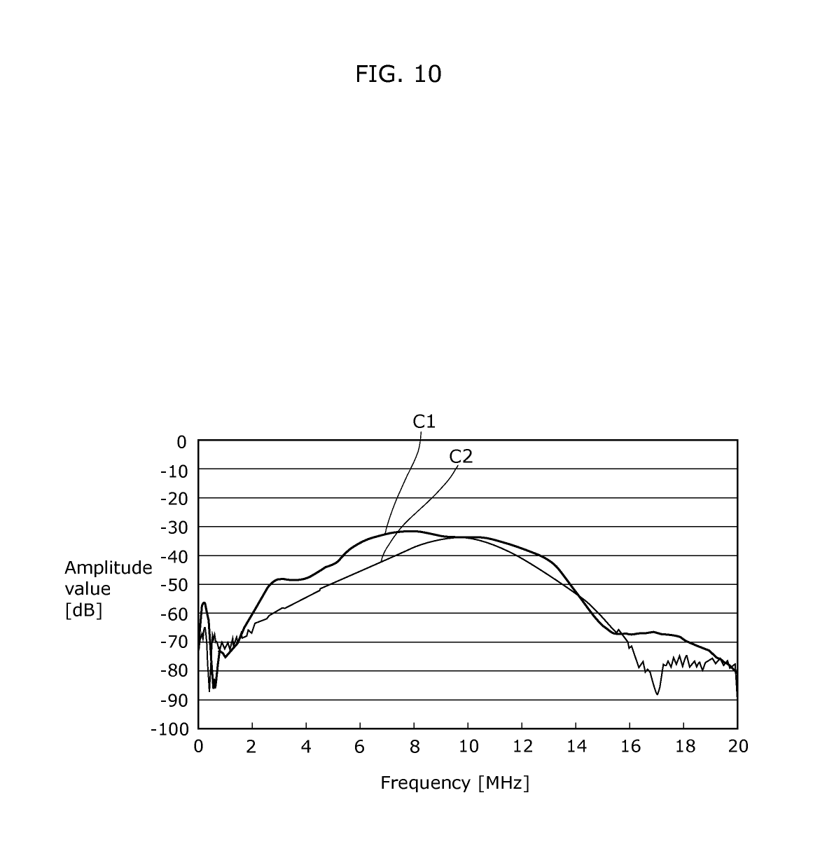

FIG. 10 shows acoustic characteristics of the acoustic matching layer according to Embodiment 3. As seen from FIG. 10, the acoustic characteristics C1 of the ultrasonic probe including the acoustic matching layer 33 with eight layers have higher fractional bandwidth compared with that of the acoustic characteristics C2 of an ultrasonic probe with no acoustic matching layer. The term “fractional bandwidth” here refers to a value obtained by dividing the bandwidth of −6 (dB) at the central frequency by the central frequency.

As described in Embodiments 1 to 3, each of the acoustic matching layers 13 to 33 with a plurality of layers includes a high impedance layer that is difficult to achieve by a conventional technique. The high impedance layer is achieved by increasing the mixing ratio of the metal materials to 90% or more and sintering the layer. Furthermore, the high impedance layer which has a porous body achieves higher mechanical bonding between adjacent layers, and increases the peeling strength decreased by the increased mixing ratio of the metal material. Accordingly, the optimal design of the structure of the acoustic matching layer having sufficient strength can be realized by simple steps. Hence, it is possible to increase sensitivity and ultrasonic frequency range of the ultrasonic probe while reducing manufacturing cost. As a result, with the ultrasonic probe as described above, an ultrasonic diagnostic apparatus can be achieved with high quality and less power consumption.

The herein disclosed subject matter is to be considered descriptive and illustrative only, and the appended Claims are of a scope intended to cover and encompass not only the particular embodiments disclosed, but also equivalent structures, methods, and/or uses.

### INDUSTRIAL APPLICABILITY

The ultrasonic probe and the method of manufacturing the ultrasonic probe according to one or more exemplary embodiments disclosed herein are applicable to an ultrasonic probe which allows efficient transmission of ultrasonic waves between piezoelectric transducers and the body, and to a method of manufacturing the ultrasonic probe.

1. An ultrasonic probe comprising:
a piezoelectric transducer which generates ultrasonic waves when a voltage is applied to the piezoelectric transducer; and
an acoustic matching layer for matching acoustic impedances between the piezoelectric transducer and a subject,
wherein the acoustic matching layer includes a sintered layer having a plurality of microscopic pores across a surface of the sintered layer, the microscopic pores being formed by sintering a composite including a bonding material and metal nanoparticles each having a size of one micron or less, and the composite has a reducing agent added which acts on an oxide layer of a surface of each of the metal nanoparticles.

2. The ultrasonic probe according to claim 1,
wherein the acoustic matching layer includes two of the sintered layers which are adjacent to each other, the two of the sintered layers being a first sintered layer and a second sintered layer, part of the first sintered layer penetrating into the microscopic pores of the second sintered layer.

3. The ultrasonic probe according to claim 1,
wherein the sintered layer is bonded to a member adjacent to the sintered layer via an adhesive layer, and
part of the adhesive layer penetrates into the microscopic pores of the sintered layer.

4. The ultrasonic probe according to claim 1,
wherein the acoustic matching layer includes four or more layers,
each of the four or more layers has a different acoustic impedance,
a layer of the four or more layers positioned closer to the piezoelectric transducer has an acoustic impedance closer to an acoustic impedance of the piezoelectric transducer, and a layer of the four or more layers positioned closer to the subject has an acoustic impedance closer to an acoustic impedance of the subject, and
at least one of the four or more layers is the sintered layer, and has an acoustic impedance of 15 MRayls or more.

5. The ultrasonic probe according to claim 4,
wherein the sintered layer that is at least one of the four or more layers includes at least 90 percent by weight metal particles.

6. The ultrasonic probe according to claim 1,
wherein the acoustic matching layer includes two of the sintered layers which are adjacent to each other, the two of the sintered layers being a first sintered layer and a second sintered layer, the first sintered layer including a first bonding material as the bonding material, the second sintered layer including a second bonding material as the bonding material, the first bonding material and the second bonding material comprising a same material, and
the first bonding material and the second bonding material are bonded to each other by being sintered.

7. The ultrasonic probe according to claim 1,
wherein the acoustic matching layer includes four or more layers, and
at least one of the four or more layers is the sintered layer formed by mixing a bonding material and resin particles, the sintered layer having an acoustic impedance of 5 MRayls or less.

8. The ultrasonic probe according to claim 1,
wherein the metal nanoparticles are either silver nanoparticles or copper nanoparticles.

9. The ultrasonic probe according to claim 1,
wherein the bonding material includes one of a silica compound and heat-resistant organic polymer resin.

10. The ultrasonic probe according to claim 1,
wherein the sintered layer is formed by sintering the composite while adding, to the composite, a reducing gas which acts on an oxide layer of a surface of each of the metal nanoparticles as the reducing agent.

11. A method of manufacturing an ultrasonic probe, the method comprising:
applying a first composite including a bonding material and metal nanoparticles each having a size of one micron or less, after diluting the first composite with a solvent;
drying the first composite applied in the applying of a first composite;
manufacturing a sintered layer having a surface formed with microscopic pores, the microscopic pores being formed by sintering the first composite dried in the drying of the first composite;
applying a second composite onto the sintered layer formed with the microscopic pores, after diluting the second composite with a solvent, the second composite including (i) a bonding material and (ii) metal nanoparticles or resin particles;
applying a third composite onto the second composite applied in the applying of a second composite, after diluting the third composite with a solvent, the third composite including (i) a bonding material comprising a material same as a material of the bonding material included in the second composite, and (ii) metal nanoparticles or resin particles; and
simultaneously sintering (i) a layer of the second composite applied in the applying of the second composite, and (ii) a layer of the third composite applied in the applying of the third composite.

12. The method of manufacturing an ultrasonic probe according to claim 11, further comprising:
applying a fourth composite different from the first composite onto the sintered layer formed with the microscopic pores, after diluting the fourth composite with a solvent;
determining whether or not the fourth composite applied in the applying of a forth composite has penetrated into the microscopic pores of the sintered layer;
drying the fourth composite applied in the applying of a fourth composite, after determined in the determining that the fourth composite has penetrated into the microscopic pores of the sintered layer; and
sintering the fourth composite dried in the drying of the fourth composite.

13. The method of manufacturing an ultrasonic probe according to claim 11, further comprising:
applying an adhesive layer or a fifth composite different from the first composite onto the sintered layer formed with the microscopic pores; and
removing air between the sintered layer and the adhesive layer to allow penetration of part of the adhesive layer or the fifth composite into the microscopic pores.
